(19) United States
(12) Patent Application Publication
(10) Pub. No.: US 2008/0122446 A1
(43) Pub. Date: May 29, 2008

(54) TEST PATTERN

(75) Inventor: Jong Kyu SONG, Seoul (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: DONGBU HITEK CO., LTD., Seoul (KR)

(21) Appl. No.: 11/872,567

(22) Filed: Oct. 15, 2007

(30) Foreign Application Priority Data
Nov. 29, 2006 (KR) 10-2006-0119239

(51) Int. Cl. G01R 31/02

(52) U.S. Cl. 324/537

(57) ABSTRACT

An example of a test pattern includes a test element, a plurality of test pads spaced apart from and formed around the test element, a plurality of metal wires configured to connect the test element with the test pads, a fuse configured to connect the test pads having the same electrical potential with each other, and a voltage pulse generator configured to generate a voltage pulse. The fuse is configured to be cut when the voltage pulse generated by the voltage pulse generator is applied to the fuse.

### CROSS-REFERENCE TO RELATED APPLICATION

This application claims priority to Korean Application No. 10-2006-0119239, filed on Nov. 29, 2006, which is incorporated herein by reference in its entirety.

### BACKGROUND

1. Field of the Invention

The invention relates to a test pattern that includes a fuse.

2. Description of the Related Art

In general, a test pattern is employed in the development of a semiconductor process technology or in process control monitoring (PCM). A test pattern is generally divided into a portion employed in the development of a semiconductor process technology and a portion employed in process control monitoring (PCM).

When employed in the development of a semiconductor process technology, a test pattern measures a variety of electrical characteristics by using a test element group (TEG) that is produced in a device manufacturing process, thereby monitoring actual device characteristics. The test pattern is formed at a scribe line area that is a boundary between individual semiconductor devices.

A test pattern typically includes a device under test (DUT) and one or more pads. The one or more pads serve as connection passages through which a voltage and a current are applied to the DUT from an external measuring instrument.

FIGS. 1A and 1B are schematic diagrams of conventional test patterns. FIG. 1A discloses several conventional test patterns that are designed to connect nodes having the same electrical potential difference to the same pad. FIG. 1B discloses a conventional test pattern that is designed to connect a pad with another pad. In the case where two or more nodes are connected to the same pad, as in the test patterns of FIG. 1A, measurements can be conveniently obtained as the reduced number of pads enables multiple characteristics of a DUT to be measured in a limited area, and human errors that may influence characteristics of a semiconductor device can be avoided.

However, a failure analysis of a DUT or an electrical characteristics test of a corresponding node may require the cutting of a wire that connects the common terminal to the node. For example, a conventional method for cutting a wire uses focused ion beam (FIB) equipment to forcibly cut the wire connecting each node. However, this conventional method is prone to human error because the complex metal wires are closely spaced. These errors can result in relatively slow and costly failure analysis of a DUT.

### SUMMARY OF EXAMPLE EMBODIMENTS

In general, example embodiments of the invention relate to a test pattern with a fuse that facilitates cutting a connection between pads that are connected to a node having the same electrical potential difference.

In one example embodiment, a test pattern of a semiconductor device includes a test element, a plurality of test pads spaced apart from and formed around the test element, a plurality of metal wires configured to connect the test element with the test pads, a fuse configured to connect the test pads having the same electrical potential with each other, and a voltage pulse generator configured to generate a voltage pulse. The fuse is configured to be cut when the voltage pulse generated by the voltage pulse generator is applied to the fuse.

### BRIEF DESCRIPTION OF THE DRAWINGS

Aspects of example embodiments of the invention will become apparent from the following description of example embodiments given in conjunction with the accompanying drawings, in which:

FIGS. 1A and 1B are schematic views of conventional test patterns;

FIG. 2 is a schematic configuration view of an example test pattern with an example fuse;

FIG. 3 is a layout view of an example polycrystalline fuse;

FIG. 4 is a schematic configuration view of another example test pattern with a pair of example fuses;

FIG. 5 is a graph showing a shape of a voltage pulse that can be applied to a fuse;

FIG. 6A is a graph showing a fuse resistance before a pulse is applied to an example polycrystalline fuse; and

FIG. 6B is a graph showing a fuse resistance after a pulse is applied to an example polycrystalline fuse.

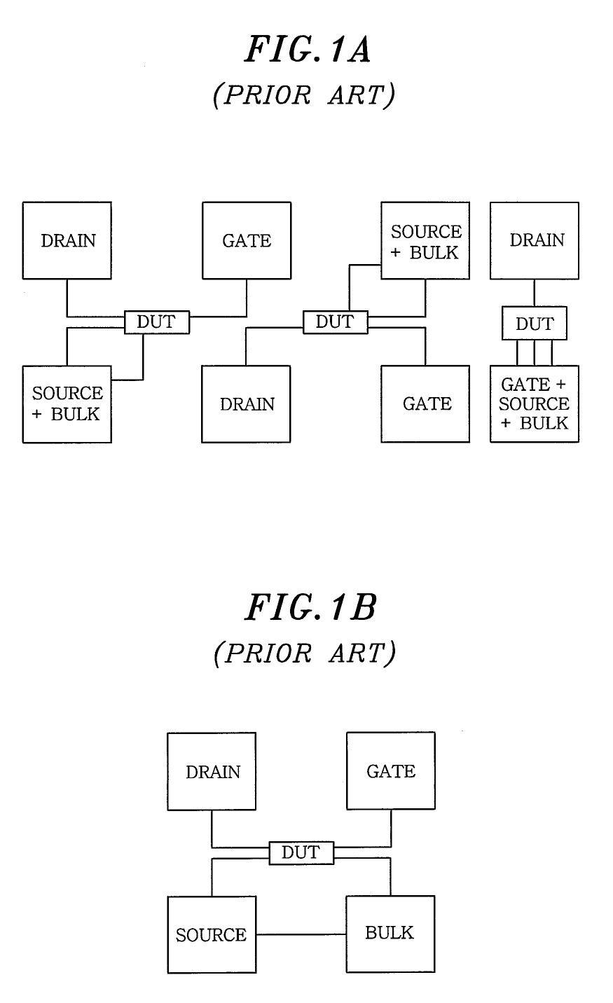

### DETAILED DESCRIPTION OF EXAMPLE EMBODIMENTS

Hereinafter, example test patterns with a fuse will be described in detail with reference to the accompanying drawings.

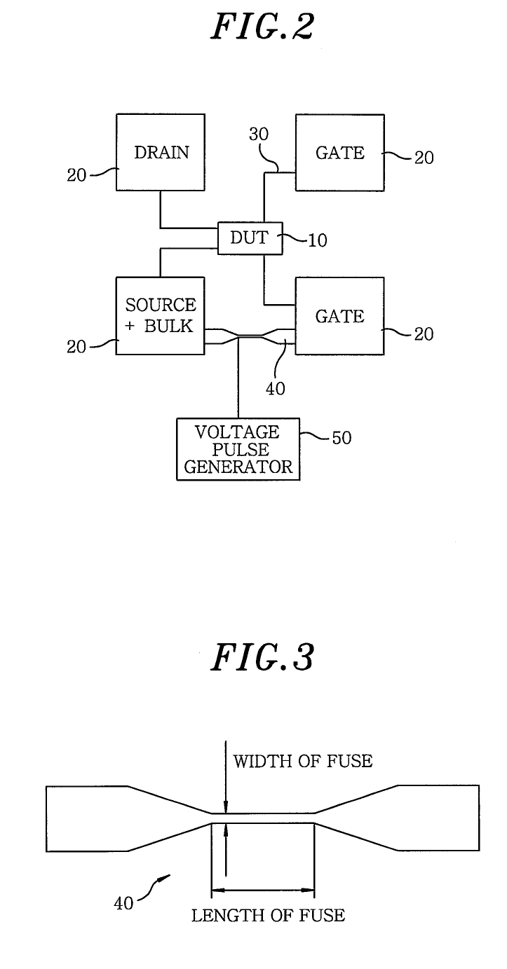

As disclosed in FIG. 2, an example test pattern includes a test element (DUT) 10, a plurality of test pads 20, a metal wire 30, a fuse 40, and a voltage pulse generator 50.

The test element 10 may be a metal oxide semiconductor field effect transistor (MOSFET) semiconductor device having diverse widths and lengths of gates, for example. The test element 10 may alternatively be another type of semiconductor device.

The test pads 20 are metal pads spaced apart from and formed around the test element 10. Each respective test pad 20 is formed of one or more metal layers and configured to receive a voltage or a current from an external measuring instrument through, for example, a probe needle contacting thereto.

The metal wires 30 connect the test pads 20 to the test element 10.

The fuse 40 connects a plurality of the test pads 20 with each other. In one example embodiment, the fuse 40 is formed of polycrystalline silicon layer. FIG. 3 discloses a width and a length of an example polycrystalline fuse 40.

The polycrystalline fuse 40 is configured such that a voltage pulse generated by the voltage pulse generator 50 applied to one-side terminal of the fuse 40 cuts the fuse 40. Characteristics of the voltage pulse include, but are not limited to, a pulse width, a duration time, and a rise time, as disclosed in FIG. 5.

During an electrical characteristics test, the fuse 40 is connected between test pads 20 that are connected to a node having the same electrical potential. Before a failure analysis for each individual test element 10 is performed, the fuse 40 is cut by applying thereto a voltage pulse generated by the voltage pulse generator 50. The fuse 40 thus serves to disconnect the test pads 20 that are commonly connected, and thus an electrical floating state can be accomplished more easily than in conventional methods in which a metal wire is physically cut by an external source, such as a focused ion beam (FIB).

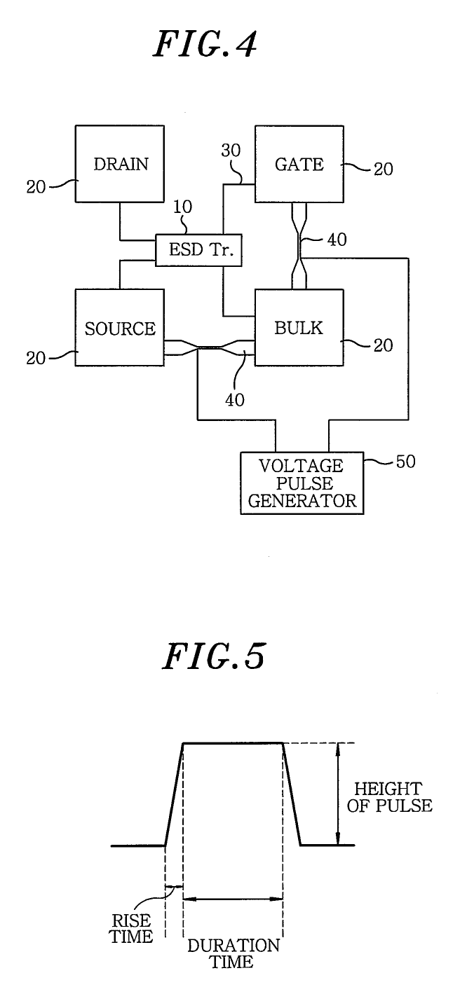

With reference now to FIG. 4, another example test pattern is disclosed. The test element 10 disclosed in FIG. 4 is an electrostatic discharge (ESD) protection transistor (ESD Tr.). The ESD protection transistor 10 is a device in which a gate, a source, and a bulk form a node that is connected to ground.

A transmission line pulse (TLP) can be used to analyze an ESD characteristic of a semiconductor device. Because a probe positioner typically only has two terminals, all nodes having the same electrical potential difference on the test pattern can be designed to be connected to a common terminal. Unfortunately, in the case where an electric failure in an ESD protection transistor occurs in a conventional device development step, it can be difficult to analyze device characteristics and to analyze a design rule margin where a gate, a source, and a bulk other than a drain are connected to the same pad.

However, the test patterns disclosed in FIG. 2 and FIG. 4 can quickly cope with a failure analysis if an electric failure occurs after analyzing an ESD characteristic.

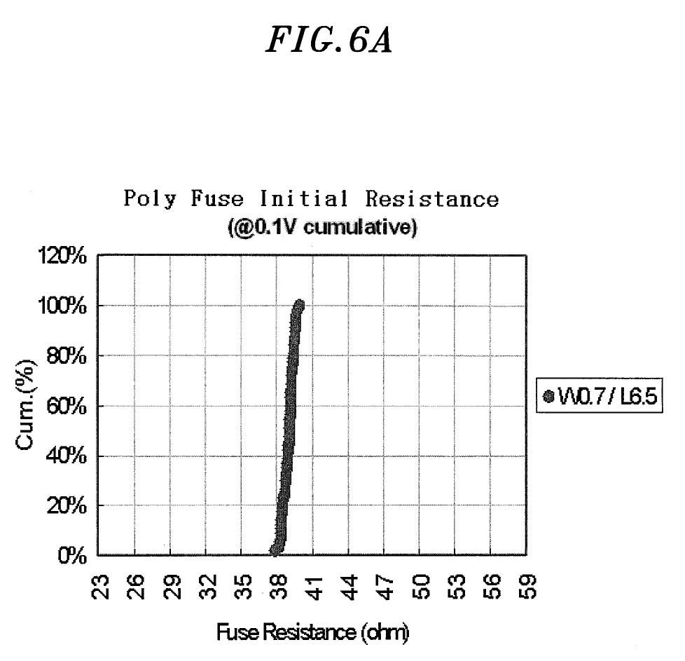

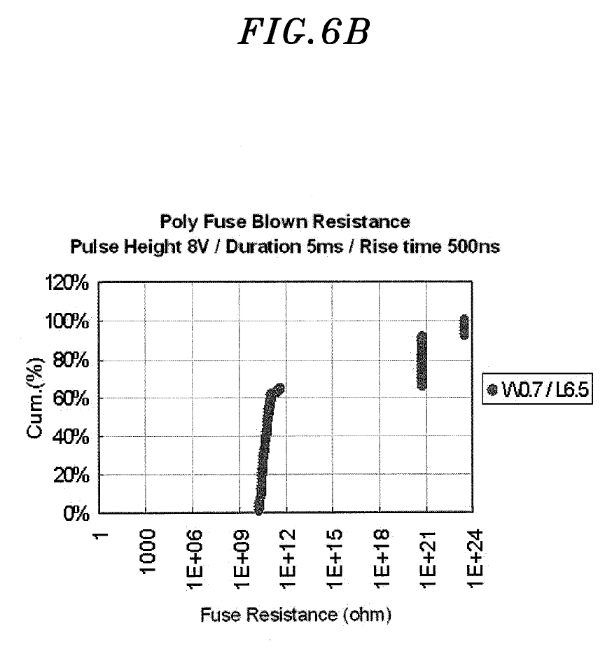

FIGS. 6A and 6B disclose experimental data where a voltage pulse having a height of about 8 V, duration of about 5 ms, and a rise time of about 500 ns is applied to cut an example polycrystalline fuse having a width and a length of about 0.7 μm and about 6.5 μm, respectively. From this experimental data, an optimal condition for cutting the example polycrystalline fuse without damaging a target semiconductor device can be analogized.

In one example embodiment, the width and the length of the example polycrystalline fuse can range from about 0.3 μm to about 1.4 μm and from about 0.5 μm to about 6.0 μm, respectively. In another example embodiment, the height, the duration, and the rise time of the voltage pulse can range from about 3 V to about 10 V, from about 5 ms to about 10 ms, and from about 50 ns to about 500 ns, respectively.

As disclosed herein in connection with FIGS. 2 and 4, where a polycrystalline fuse is provided between pads that are connected to a node having the same electrical potential difference, connections between the pads can be easily cut, thereby resulting in a relatively fast and inexpensive failure analysis of a test element. Since pads having the same electrical potential difference are connected to a common terminal, any external voltage may be applied to the pad connected to the common terminal at the time of testing device characteristics. Therefore, where pads have the same electrical potential difference, a certain test pattern can measure electrical characteristics of a semiconductor device by using only two terminals in the case of a MOSFET, thereby making measurement more convenient. Also, utilization of an SMU module of a measuring instrument can further reduce costs.

The example test patterns disclosed herein are not limited to a MOSFET, and can also be employed in any application where it proves beneficial to employ a connection to nodes having the same electrical potential difference via a fuse in order to measure electrical characteristics. In such application, when each node requires a different electrical potential difference, the fuse can be cut to analyze electrical characteristics of each node separately.

While example embodiments of the invention have been disclosed herein, various changes and modifications may be made without departing from the scope of the example embodiments.

What is claimed is:

1. A test pattern comprising:
a test element;
a plurality of test pads spaced apart from and formed around the test element;
a plurality of metal wires configured to connect the test element with the test pads;
a fuse configured to connect the test pads having the same electrical potential with each other; and
a voltage pulse generator configured to generate a voltage pulse;
wherein the fuse is configured to be cut when the voltage pulse generated by the voltage pulse generator is applied to the fuse.

2. The test pattern of claim 1, wherein the fuse comprises a polycrystalline silicon layer.

3. The test pattern of claim 1, wherein the test element comprises an electrostatic discharge protection transistor.

4. The test pattern of claim 1, wherein the test element comprises a metal oxide semiconductor field effect transistor (MOSFET) semiconductor device.

5. The test pattern of claim 1, wherein a width and a length of the fuse range from about 0.3 μm to about 1.4 μm and from about 0.5 μm to about 6.0 μm, respectively.

6. The test pattern of claim 5, wherein the width and the length of the fuse are about 0.7 μm and 6.5 μm, respectively.

7. The test pattern of claim 1, wherein a height, a duration and a rise time of the voltage pulse range from about 3 V to about 10 V, from about 5 ms to about 10 ms, and from about 50 ns to about 500 ns, respectively.

8. The test pattern of claim 7, wherein the height, the duration and the rise time of the voltage pulse are about 8 V, about 5 ms, and about 500 ns, respectively.

9. A test pattern comprising:
a test element;
a plurality of test pads spaced apart from and formed around the test element;
a plurality of metal wires configured to connect the test element with the test pads;
a plurality of fuses configured to connect the test pads having the same electrical potential with each other; and
a voltage pulse generator configured to generate a voltage pulse;
wherein each fuse is configured to be cut when the voltage pulse generated by the voltage pulse generator is applied to the fuse.

10. The test pattern of claim 9, wherein the fuse comprises a polycrystalline silicon layer.

11. The test pattern of claim 9, wherein the test element comprises an electrostatic discharge protection transistor.

12. The test pattern of claim 9, wherein the test element comprises a metal oxide semiconductor field effect transistor (MOSFET) semiconductor device.

13. The test pattern of claim 9, wherein a width and a length of the fuse range from about 0.3 μm to about 1.4 μm and from about 0.5 μm to about 6.0 μm, respectively.

14. The test pattern of claim 13, wherein the width and the length of the fuse are about 0.7 μm and 6.5 μm, respectively.

15. The test pattern of claim 9, wherein a height, a duration and a rise time of the voltage pulse range from about 3 V to about 10 V, from about 5 ms to about 10 ms, and from about 50 ns to about 500 ns, respectively.

16. The test pattern of claim 15, wherein the height, the duration and the rise time of the voltage pulse are about 8 V, about 5 ms, and about 500 ns, respectively.
